(19) United States
(12) Patent Application Publication
(10) Pub. No.: US 2025/0006508 A1
(43) Pub. Date: Jan. 2, 2025

(54) METHOD OF MANUFACTURING LEAD FRAME

(71) Applicant: HAESUNG DS CO., LTD, Gyeongsangnam-do (KR)

(72) Inventors: Gwang Ryeol PARK, Gyeongsangnam-do (KR); Sung Il KANG, Gyeongsangnam-do (KR); In Sub BAE, Gyeongsangnam-do (KR); Min Young HONG, Gyeongsangnam-do (KR); Ho Jun RYU, Gyeongsangnam-do (KR); Won Young HEO, Gyeongsangnam-do (KR); In Pyo HONG, Gyeongsangnam-do (KR)

(21) Appl. No.: 18/732,916

(22) Filed: Jun. 4, 2024

(30) Foreign Application Priority Data
Jun. 5, 2023 (KR) 10-2023-0072344

(51) Int. Cl. H01L 21/48; H01L 21/02

(52) U.S. Cl. CPC H01L 21/4842; H01L 21/4828; H01L 21/02227

(57) ABSTRACT

According to embodiments of the present disclosure, a method of manufacturing a lead frame includes preparing a base frame on which a conductive pattern is formed, preparing a surface treatment solution containing an alkaline substance and a silicon-containing compound, and forming a siloxane layer on the conductive pattern by applying the surface treatment solution onto the base frame, wherein the forming of the siloxane layer includes forming an oxide layer including a hydroxyl group bonded to the conductive pattern, and bonding the silicon-containing compound to the conductive pattern by causing the hydroxyl group and the silicon-containing compound to react with each other, and the reacting of the silicon-containing compound and the forming of the oxide layer are performed in a single process.

### CROSS-REFERENCE TO RELATED APPLICATION

This application is based on and claims priority under 35 U.S.C. § 119 to Korean Patent Application No. 10-2023-0072344, filed on Jun. 5, 2023, in the Korean Intellectual Property Office, the disclosure of which is incorporated by reference herein in its entirety.

### BACKGROUND

### 1. Field

The present disclosure relates to a lead frame, and particularly, to a method of manufacturing a lead frame.

### 2. Description of the Related Art

Semiconductor packages may include a lead frame, a semiconductor chip, and a molding film. A semiconductor chip may include a single device including various electronic circuits and wiring, an integrated circuit, or a hybrid circuit. Lead frames may act as a lead that connects the input/output pad of a semiconductor chip to an electrical circuit formed on a main board, and may act as a supporter that fixes a semiconductor package on a main board. A semiconductor chip may be placed on the center area of a lead frame. A molding film may protect a semiconductor chip from various external environments such as dust, moisture, and electrical and mechanical loads. A semiconductor package may be manufactured by connecting electrodes of a semiconductor chip to a lead portion of a lead frame via a bonding wire and encapsulating the semiconductor chip, the lead portion, and the bonding wire with a molding resin. At this time, the molding film may be peeled off from the lead frame.

### SUMMARY

The objective to be addressed by the present disclosure is to provide a method of manufacturing a lead frame efficiently and easily.

According to embodiments of the present disclosure, a method of manufacturing a lead frame includes preparing a base frame on which a conductive pattern is formed, preparing a surface treatment solution containing an alkaline substance and a silicon-containing compound, and forming a siloxane layer on the conductive pattern by applying the surface treatment solution onto the base frame, wherein the forming the siloxane layer includes forming an oxide layer including a hydroxyl group bonded to the conductive pattern, and bonding the silicon-containing compound to the conductive pattern by causing the hydroxyl group and the silicon-containing compound to react each other, and the reacting the silicon-containing compound and the forming the oxide layer are performed in a single process.

According to an embodiment, the siloxane layer may be formed by an electro-deposition process.

According to another embodiment, the electro-deposition process may be performed for 0.1 seconds to 600 seconds under the current density condition of 0.1 A/dm² to 50 A/dm².

In an embodiment, the siloxane layer may be formed by a dipping process.

In an embodiment, the silicon-containing compound may include a material represented by Formula 1.

R₁—(CH₂)ₙ—Si—(OR₂)₃ Formula 1

In Formula 1, R₁ may be one selected from —NH₂, —SH, a glycidyloxy group, a substituted or unsubstituted amino group having 1 to 10 carbon atoms, a substituted or unsubstituted alkyl sulfide group having 1 to 10 carbon atoms, a substituted or unsubstituted mercapto group having 1 to 10 carbon atoms, a substituted or unsubstituted epoxide group having 1 to 10 carbon atoms, and a substituted or unsubstituted ether group having 1 to 10 carbon atoms, and R₂ is an alkyl group having 1 to 5 carbon atoms, and n is an integer from 1 to 50.

In an embodiment, R₂ in Formula 1 may be an ethyl group or a methyl group.

In an embodiment, the alkaline substance may include at least one of NaOH, Na₂CO₃, and/or Na₂SiO.

In an embodiment, the concentration of the silicon-containing compound in the surface treatment solution may be 0.0001 g/L to 10 g/L.

In an embodiment, the alkaline substance includes the first alkaline substance, the second alkaline substance, and the third alkaline substance which are different from each other, and the concentration of the first alkaline substance is 10 g/L to 200 g/L, the concentration of the second alkaline substance may be 10 g/L to 200 g/L, and the concentration of the third alkaline substance may be 10 g/L to 200 g/L.

In an embodiment, the silicon-containing compound may include at least one of (3-aminopropyl)triethoxysilane, 3-mercaptopropyltrimethoxysilane and (3-glycidyloxypropyl)triethoxysilane.

In an embodiment, the conductive pattern may expose at least a portion of the first surface of the base frame, and the siloxane layer may be further formed on the exposed first surface of the base frame.

In an embodiment, the base frame may include a first metal, the conductive pattern may include a second metal different from the first metal, and the siloxane layer on the base frame may be bonded with the first metal, and the siloxane layer on the conductive pattern may be bonded with the second metal.

In an embodiment, the siloxane layer on the conductive pattern may be connected to the siloxane layer on the base frame.

In an embodiment, preparing the base frame includes: forming a hole passing through the first surface and the second surface of the base frame to form a die pad portion and lead portions spaced apart therefrom; and forming the conductive pattern on the first surface of the base frame.

In an embodiment, a rough process may be further performed on the first surface of the base frame.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 to 5 are cross-sectional views for explaining a method of manufacturing a lead frame, according to embodiments.

FIG. 6 is a cross-sectional view for explaining a lead frame according to another embodiment.

FIG. 7 is a cross-sectional view for explaining a semiconductor package according to embodiments.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Expressions such as “at least one of,” when preceding a list of elements, modify the entire list of elements and do not modify the individual elements of the list.

The present disclosure will become clear by referring to the embodiments described in detail below along with the accompanying drawings. However, the present disclosure is not limited to the embodiments disclosed below and will be implemented in various different forms. The present embodiments only serve to ensure that the disclosure of the present disclosure is complete and to inform a person skilled in the art, to which the present disclosure pertains, of the scope of the disclosure fully, and the present disclosure is only defined by the scope of the claims. Meanwhile, the terms used in this specification are for describing embodiments and are not intended to limit the present disclosure. Throughout the present specification, singular forms also include plural forms, unless specifically stated otherwise in the context. When wording “comprises” and/or “comprising” are used to describe a component, a step, an operation and/or a device, the wording does not preclude the presence or addition of one or more other components, steps, operations and/or devices. Terms such as first, second, etc. may be used to describe various components, but the components should not be limited by the terms. Terms are used only to distinguish one component from another.

The wording “substituted or unsubstituted” as used herein refers to unsubstitution or substitution with one or more substituent selected from the group consisting of a hydrogen atom, a deuterium atom, a halogen atom, an amino group, a silyl group, a sulfide group, a mercapto group, an epoxide group, an alkyl group, and an ether group. In detail, the wording “substituted or unsubstituted” refers to unsubstitution or substitution with one or more substituents selected from the group consisting of an amino group, a sulfide group, a mercapto group, an epoxide, an alkyl group, and an ether group. Additionally, each of the substituents as listed above may be substituted or unsubstituted. For example, a methyl amino group may be interpreted as an amino group.

The alkyl group may be a linear alkyl group, a branched alkyl group, or a cyclic alkyl group. The number of carbon atoms of the alkyl group is not particularly limited, and may be an alkyl group having 1 to 50 carbon atoms. For example, the alkyl group may have 1 to 10 carbon atoms.

Throughout this specification, like reference numerals may refer to like elements. Hereinafter, a lead frame, a method of manufacturing the lead frame, and a semiconductor package including the lead frame according to the concept of the present disclosure will be described.

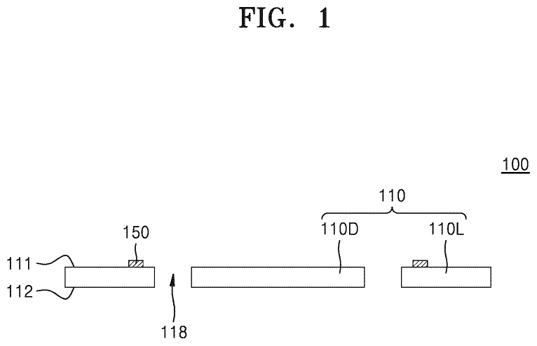

FIGS. 1 to 5 are cross-sectional views for explaining a method of manufacturing a lead frame according to embodiments.

Referring to FIG. 1, a base frame 110 may be prepared. The base frame 110 may include a first metal. In an embodiment, the base frame 110 may include copper and/or a copper alloy. In an embodiment, the base frame 110 may include gold (Au), silver (Ag), palladium (Pd), nickel (Ni), and/or alloys thereof. The base frame 110 may include a strike plating layer, but is not limited thereto.

The base frame 110 may have a first surface 111 and a second surface 112 which face each other. A base frame 110 may have a hole 118 passing the first surface 111 and the second surface 112. In an embodiment, the hole 118 may be formed using a wet etching method. In an embodiment, the formation of the hole 118 may be performed by a physical method such as a stamping method or a punching method.

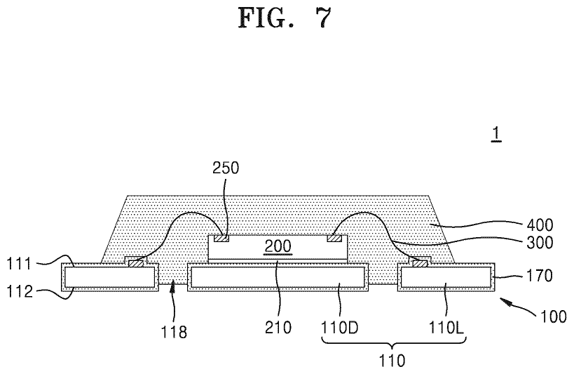

Due to the formation of the hole 118, the base frame 110 may have a die pad portion 110D and lead portions 110L. The hole 118 of the base frame 110 may be disposed between the die pad portion 110D and the lead portions 110L. The die pad portion 110D of the base frame 110 may be spaced apart from the lead portions 110L by the hole 118. The die pad portion 110D of the base frame 110 may be provided in a center area of the base frame 110, from a plan view. The die pad portion 110D may be an area where a semiconductor chip 200, which will be described later in FIG. 7, is disposed. The lead portions 110L of the base frame 110 may be disposed in an edge area of the base frame 110, from a plan view. The lead portions 110L of the base frame 110 may be arranged to surround the die pad portion 110D from a plan view.

According to embodiments, a rough process may be further performed on the first surface 111 of the base frame 110. The rough process may be a process that increases surface roughness. At this time, the second surface 112 of the base frame 110 and the inner wall of the hole 118 may not be exposed to the rough process. Accordingly, the surface roughness of the first surface 111 of the base frame 110 may be increased. For example, the surface roughness of the first surface 111 of the base frame 110 may be greater than the surface roughness of the second surface 112 of the base frame 110. In an embodiment, performing the rough process may be omitted.

Conductive patterns 150 may be formed on the base frame 110. Forming the conductive patterns 150 may be performed during a plating process. The conductive patterns 150 may be strike plated layers, but embodiments are not limited thereto. For example, forming the conductive patterns 150 may include performing a selective plating process on the first surface 111 of the base frame 110. In this case, forming the conductive patterns 150 may include forming a mask layer on the base frame 110 and performing a plating process on the base frame 110 exposed to the mask layer. The mask pattern may have an opening that exposes the first surface 111 of the base frame 110. The opening of the mask pattern may have a ring shape, a double ring shape, a spot shape, or a double spot shape, from a plan view. The planar shape of the opening of the mask pattern is not limited thereto and may be modified in various ways. The mask pattern may include a physical or mechanical mask, such as a masking tool. In an embodiment, the mask pattern may include masking tape or a reel mask, a rubber mask, or a cut-strip mask.

The conductive patterns 150 may be disposed on the first surface 111 of the lead portions 110L as shown in FIG. 1. The conductive patterns 150 may expose a portion of the first surface 111 of the lead portions 110L of the base frame 110 and the first surface 111 of the die pad portion 110D. The arrangement of the conductive patterns 150 may be modified in various ways. In an embodiment, at least one of the conductive patterns 150 may be further provided on the first surface 111 of the die pad portion 110D. In this case, the conductive patterns 150 may be disposed on the lead portions 110L and the die pad portion 110D. In an embodiment, at least one of the conductive patterns 150 may entirely cover the first surface 111 of the die pad portion 110D or may cover a portion of the first surface 111 of the die pad portion 110D. In an embodiment, at least one of the conductive patterns 150 may be further provided on the second surface 112 of the base frame 110.

The conductive patterns 150 may each have a thickness of 3 μm to 7 μm. The width of each of the conductive patterns 150 may be 0.1 μm to 10 μm. The length of each of the conductive patterns 150 may be 0.1 μm to 10 μm.

The conductive patterns 150 may each include a second metal. The second metal may be different from the first metal. In an embodiment, the second metal may include silver (Ag). In an embodiment, the second metal may include copper, gold (Au), palladium (Pd), nickel (Ni), and/or alloys thereof.

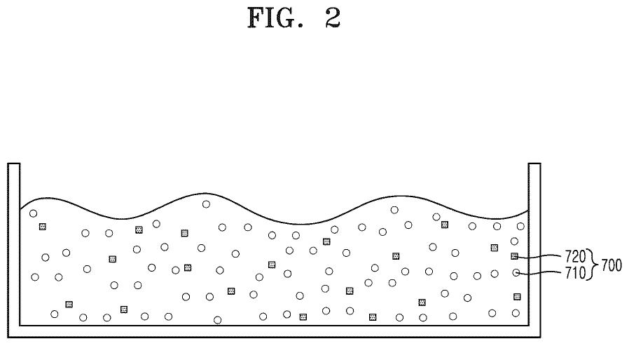

Referring to FIG. 2, a surface treatment solution 700 may be prepared. The surface treatment solution 700 may include an alkaline substance 710 and a first silicon-containing compound 720. The surface treatment solution 700 may be an aqueous solution. The surface treatment solution 700 may function as an adhesion promoter. For example, the alkaline substance 710 may include NaOH, Na₂CO₃, and/or Na₂SiO₃. The alkaline substance 710 may include a first alkaline substance, a second alkaline substance, and a third alkaline substance, which are different from each other. In an embodiment, the first alkaline substance includes NaOH and may function as a surfactant. The concentration of the first alkaline substance may be 10 g/L to 200 g/L. The second alkaline substance includes Na₂CO₃ and may function as a stabilizer. The concentration of the second alkaline substance may be 10 g/L to 200 g/L. The third alkaline substance may include Na₂SiO₃ and may function as a stabilizer. The concentration of the third alkaline substance may be 10 g/L to 200 g/L. However, the alkaline substance 710 is not limited to the first alkaline substance, the second alkaline substance, and the third alkaline substance, and may be modified in various ways.

The first silicon-containing compound 720 may be represented by Formula 1. The first silicon-containing compound 720 may be alkyl alkoxy silane or alkyl silanol, and the alkyl group may be substituted or unsubstituted.

R₁—(CH₂)ₙ—Si—(OR₂)₃ Formula 1

In Formula 1, R₁ may include one selected from —NH₂, —SH, a glycidyloxy group, a substituted or unsubstituted alkyl amino group having 1 to 10 carbon atoms, a substituted or unsubstituted alkyl sulfide group having 1 to 10 carbon atoms, a substituted or unsubstituted mercapto group having 1 to 10 carbon atoms, a substituted or unsubstituted epoxide group having 1 to 10 carbon atoms, and a substituted or unsubstituted alkyl ether group having 1 to 10 carbon atoms, and R₂ is an alkyl group having 1 to 5 carbon atoms, and n is an integer from 1 to 50.

According to an embodiment, R₁ may be —NH₂, —SH, and/or a glycidyloxy group.

According to an embodiment, R₂ may be a methyl group or an ethyl group.

According to an embodiment, n may be an integer from 1 to 10.

According to an embodiment, the first silicon-containing compound 720 may include at least one of a material represented by Formula 2, a material represented by Formula 3, and a material represented by Formula 4.

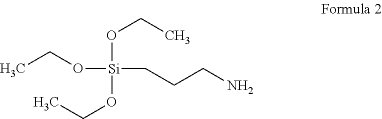

The material represented by Formula 2 may be (3-aminopropyl)triethoxysilane (APTES).

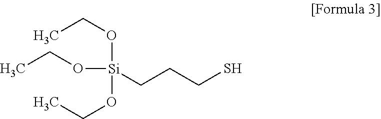

The material represented by Formula 3 may be 3-mercaptopropyltrimethoxysilane (MPTES).

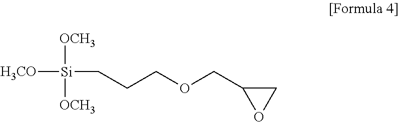 [SMILES: CO[Si](CCCOCC1CO1)(OC)OC]

The material represented by Formula 4 may be (3-glycidyloxypropyl)triethoxysilane (GPTES).

The concentration of the first silicon-containing compound 720 may be 0.0001 g/L to 10 g/L. The concentration of the first silicon-containing compound 720 may be smaller than each of the concentration of the first alkaline substance, the concentration of the second alkaline substance, and the concentration of the third alkaline substance, but is not limited thereto.

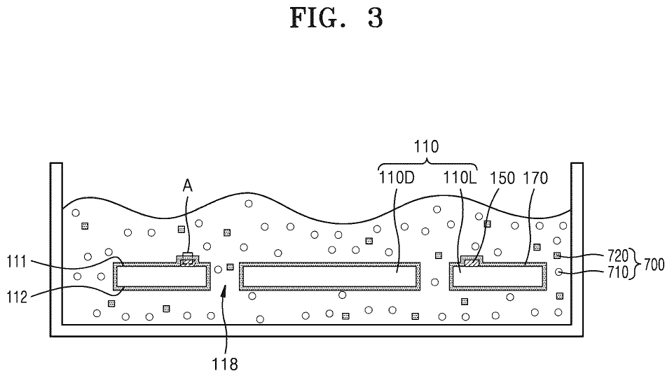

Referring to FIG. 3, the surface treatment solution 700 may be applied to the base frame 110 and the conductive patterns 150 to form a siloxane layer 170. In an embodiment, the siloxane layer 170 may be formed by a dipping process of providing the base frame 110 in the surface treatment solution 700. In an embodiment, after the base frame 110 is provided in the surface treatment solution 700, an electro-deposition process may be performed by using the surface treatment solution 700. As a result of the electro-deposition process, the siloxane layer 170 may be formed. For example, during the electro-deposition process, titanium or titanium oxide may be used as an anode, and silver foil (Ag foil) may be used as a cathode, but embodiments are not limited thereto.

The siloxane layer 170 may be formed on the base frame 110 and the conductive patterns 150 to cover the base frame 110 and the conductive patterns 150. Hereinafter, the formation of the siloxane layer 170 will be described in more detail.

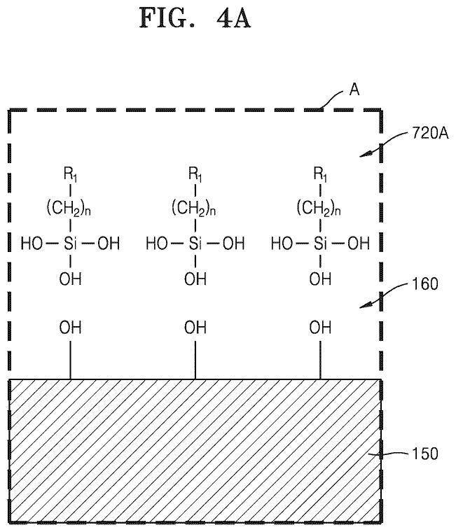

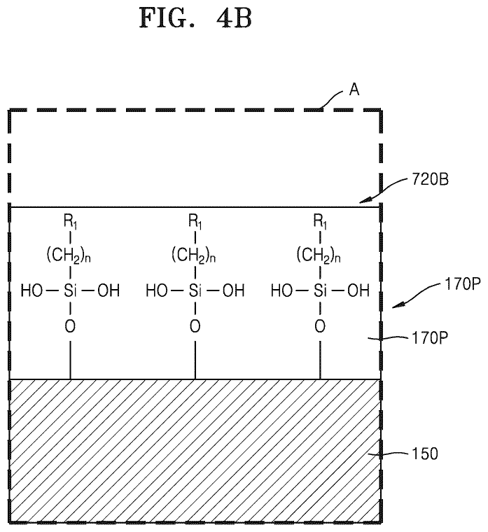

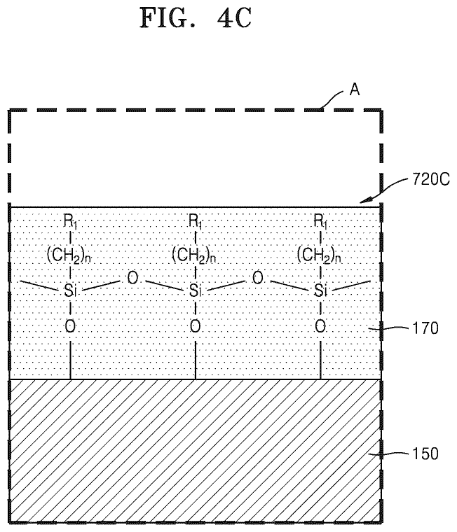

FIGS. 4A to 4C are diagrams for explaining the formation process for a siloxane layer according to embodiments, and are enlarged views of area A of FIG. 3. Hereinafter, a singular conductive pattern will be described.

Referring to FIGS. 3 and 4A, an oxide layer 160 may be formed on the conductive pattern 150 by the alkaline substance 710 included in the surface treatment solution 700. The oxide layer 160 formed on the conductive pattern 150 may include an oxide of a second metal (for example, silver oxide). The oxide layer 160 may be a temporary layer. Since the alkaline substance 710 has the concentration ranges described above, the oxide layer 160 may be formed well. Although not shown, an oxide layer 160 may be formed on the base frame 110. The oxide layer 160 formed on the base frame 110 may include an oxide of the first metal (for example, copper oxide). The oxide layer 160 may include a hydroxyl group, an oxygen anion, or an oxygen atom, bonded to the first metal or the second metal.

According to embodiments, the silicon-containing compound (720 in FIG. 3) in the surface treatment solution 700 may be hydrolyzed as shown in Reaction Scheme 1 to form a hydrolyzed first silicon-containing compound (720A in FIG. 4A). The first silicon-containing compound which is hydrolyzed (720A in FIG. 4A) may be silanol. The first silicon-containing compound which is hydrolyzed (720A in FIG. 4A) may have a hydroxyl group (OH) bonded to Si.

R₁—(CH₂)ₙ—Si—(OR₂)₃₊3H₂O→R₁—(CH₂)ₙ—Si—(OH)₃₊3R₂OH Reaction Scheme 1

In Reaction Scheme 1, R₁, n, and R₂ are as defined in connection with Formula 1.

According to embodiments, since R₂ is an alkyl group having 1 to 5 carbon atoms, the hydrolysis reactivity of the first silicon-containing compound 720 as shown in Reaction Scheme 1 may be improved. For example, when R₂ is an ethyl group or a methyl group, the hydrolysis reactivity of the first silicon-containing compound 720 may be further improved.

Referring to FIGS. 3 and 4B, the first silicon-containing compound which is hydrolyzed 720A may react with the oxide layer 160 to form a preliminary siloxane layer 170P. According to embodiments, water in the surface treatment solution 700 may be decomposed as shown in Reaction Scheme 2, and hydroxide ions (OH—) may be formed. When an electro-deposition process is performed, hydroxide ions may be formed easily. Thereafter, the hydroxyl group of the first silicon-containing compound which is hydrolyzed 720A may react with the hydroxyl group of the first metal or the second metal as shown in Reaction Scheme 2 to form a Si—O-M bond. Accordingly, the preliminary siloxane layer 170P may be formed. The preliminary siloxane layer 170P may include second silicon-containing compounds 720B, and each of the second silicon-containing compounds 720B may be bonded on the conductive pattern 150 or the base frame (110 in FIG. 3) through Si—O-M bonding. At this time, each of the second silicon-containing compounds 720B is derived from the first silicon-containing compound 720 of Formula 1 and FIG. 3, and may have a different chemical structure from the first silicon-containing compound 720 of Formula 1. The hydroxide ion formed by Reaction Scheme 2 may act as a catalyst for Reaction Scheme 3.

The second silicon-containing compounds 720B may be bonded to the conductive pattern 150. Although not shown, the second silicon-containing compounds 720B may be bonded to the base frame 110.

2H₂O+2e⁻→H₂+2OH⁻ Reaction Scheme 2

R₁—(CH₂)ₙ—Si—(OH)₃+M-OH→R₁—(CH₂)ₙ—Si(OH)₂—O-M+H₂O Reaction Scheme 3

In Reaction Scheme 3, R₁ and n are as defined in connection with Formula 1, and M may be a metal on the surface of the base frame or a metal on the surface of the conductive pattern.

Referring to FIGS. 3 and 4C, adjacent second silicon-containing compounds 720B in the preliminary siloxane layer 170P may react with each other to form a Si—O—Si bond. The reaction may be a condensation reaction. Accordingly, adjacent ones of the second silicon-containing compounds 720B may be bonded to each other by Si—O—Si bond to form third silicon-containing compounds 720C. Accordingly, the siloxane layer 170 may be formed from the preliminary siloxane layer 170P. That is, the siloxane layer 170 includes third silicon-containing compounds 720C bonded to each other by a Si—O—Si bond, and each of silicon elements of the third silicon-containing compounds 720C may be bonded to the first metal or the second metal. At this time, the third silicon-containing compounds 720C may be derived from the first silicon-containing compound 720 of Formula 1 and FIG. 3, and the second silicon-containing compounds 720B of FIG. 4B, and may have a different chemical structure from the first silicon-containing compound 720 of Formula 1 and the second silicon-containing compounds 720B of FIG. 4B. The third silicon-containing compounds 720C may each be siloxane. Since the concentration of the first silicon-containing compound 720 satisfies the conditions described above, the siloxane layer 170 may be formed well.

The siloxane layer 170 on the base frame (110 in FIG. 3) may be bonded to the first metal. The siloxane layer 170 on the conductive patterns 150 may be bonded to a second metal. The siloxane layer 170 on the conductive patterns 150 and the siloxane layer 170 on the base frame 110 may be formed using a single process. Accordingly, the siloxane layer 170 on the conductive patterns 150 may be connected to the siloxane layer 170 on the base frame 110. Accordingly, the process of forming the siloxane layer 170 may be simplified.

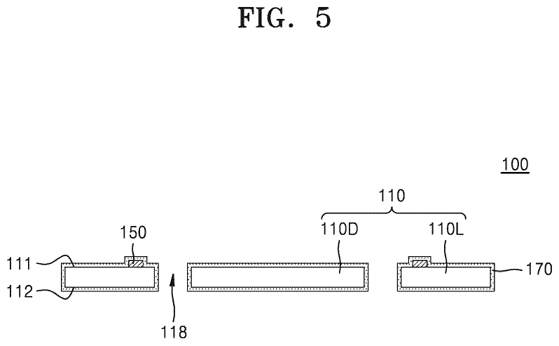

When the siloxane layer 170 is formed through a separate process from the formation of the oxide layer 160, the process for forming the siloxane layer 170 and the lead frame (110 in FIG. 5) may become complicated and process efficiency thereof may be decreased. According to embodiments, the oxide layer 160 in FIG. 4A and the siloxane layer 170 in FIG. 4C may be formed using a single process. Accordingly, the formation process for the siloxane layer 170 may be simplified and process efficiency thereof may be improved.

When the oxide layer 160 and the siloxane layer 170 are formed by an electro-deposition process, the siloxane layer 170 may exhibit more structured and uniform film properties. The electro-deposition process may be performed for 0.1 seconds to 600 seconds under the current density condition of 0.1 A/dm² (ASD) to 50 A/dm² (ASD). ASD may refer to amps (ampere) per decimeter squared. When the electro-deposition process satisfies the current density condition and the process time condition, the siloxane layer 170 may be formed well. Additionally, the manufacturing process efficiency for the siloxane layer 170 may be improved.

Referring to FIG. 5, the base frame 110 on which the siloxane layer 170 is formed, may be taken out from the surface treatment solution (700 in FIG. 3). Manufacturing of the lead frame 100 may be completed using the examples described above. The lead frame 100 may include the base frame 110, the conductive patterns 150, and the siloxane layer 170. The siloxane layer 170 may be formed on the base frame 110 and the conductive patterns 150 to cover the first surface 111 of the base frame 110 and the conductive patterns 150. The siloxane layer 170 may extend further onto the inner wall of the hole 118. The siloxane layer 170 may extend further onto the outer wall of the base frame 110. The siloxane layer 170 may further cover the second surface 112 of the base frame 110. Unlike shown, the siloxane layer 170 may not cover the second surface 112 of the base frame 110.

Hereinafter, the preparation of a surface treatment solution according to an experimental example will be described.

### Experimental Example

A mixed solution containing 30 g/L of NaOH (98%, Samchun), 30 g/L of Na₂CO₃ (99%, Samchun), and 20 g/L of Na₂SiO₃ was prepared. In this regard, Na₂SiO₃ was prepared by mixing 47.0% to 53.0% Na₂O and 46.0% to 52.0% SiO₂. The mixed solution was allowed to rise to 90° C., then stirred for 1 hour to obtain a clear mixed solution, and the clear mixed solution was cooled to 25° C. 10 ml/L of (3-Aminopropyl)triethoxysilane (APTES, 99%: Sigma-Aldrich), (3-mercaptopropyl)triethoxysilane (MPTES, >80%: SigmaAldrich), or (3-gycidyloxypropyl) trimethoxysilane (GPTMS, >98%: SigmaAldrich) were added to the cooled mixed solution to prepare a surface treatment solution 700. Afterwards, the surface treatment solution is stirred for about 30 minutes. By stirring, a first silicon-containing compound in the surface treatment solution can be hydrolyzed as shown in Reaction Scheme 1 to form silanol.

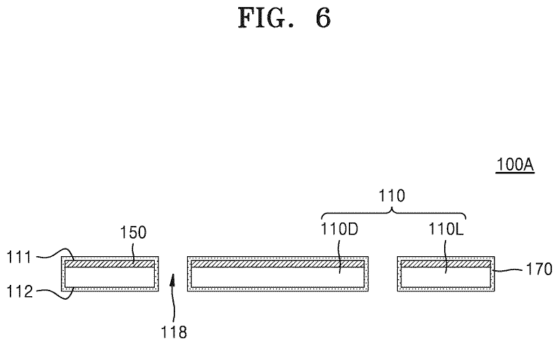

FIG. 6 is a cross-sectional view for explaining a lead frame according to another embodiment.

Referring to FIG. 6, a lead frame 100A may include a base frame 110, conductive patterns 150, and a siloxane layer 170. The base frame 110 and the conductive patterns 150 may be substantially the same as described in connection with FIG. 1. However, the conductive patterns 150 are formed on the first surface 111 of the base frame 110 and may not expose the first surface 111 of the base frame 110. For example, the conductive patterns 150 may cover the first surface 111 of the lead portions 110L and the first surface 111 of the die pad portion 110D.

The siloxane layer 170 may be formed by the method described in the embodiments explained in connection with FIGS. 2 to 5. The siloxane layer 170 may cover the top surfaces and sidewalls of the conductive patterns 150. The siloxane layer 170 may extend further onto the inner wall of the hole 118. The siloxane layer 170 may not cover the second surface 112 of the base frame 110. Unlike shown, the siloxane layer 170 may further cover the second surface 112 of the base frame 110.

FIG. 7 is a cross-sectional view for explaining a semiconductor package according to embodiments.

Referring to FIG. 7, a semiconductor package 1 may include a lead frame 100, a semiconductor chip 200, bonding wires 300, and a molding film 400. The semiconductor package 1 may be formed using the lead frame 100 manufactured as in the embodiments described in connection with FIGS. 1 to 5. Alternatively, the semiconductor package 1 may be manufactured using the lead frame 100A of FIG. 6 instead of the lead frame 100 of FIG. 5.

The semiconductor chip 200 may be mounted on the lead frame 100. The semiconductor chip 200 may be mounted on the first surface 111 of the die pad portion 110D of the base frame 110. The semiconductor chip 200 may be spaced apart from the lead portions 110L and the conductive patterns 150. The semiconductor chip 200 may include chip pads 250 and integrated circuits. Integrated circuits are provided within the semiconductor chip 200 and may include memory circuits, logic circuits, or a combination thereof. The chip pads 250 are provided on the top surface of the semiconductor chip 200 and may be electrically connected to integrated circuits. The chip pads 250 may include metal materials such as aluminum, gold, copper, nickel, and/or a combination thereof.

The semiconductor package 1 may further include an adhesive film 210. The adhesive film 210 may be disposed between the lead frame 100 and the semiconductor chip 200. The semiconductor chip 200 may be attached onto the first surface 111 of the base frame 110 through the adhesive film 210. The adhesive film 210 is provided on the die pad portion 110D of the base frame 110, and may be spaced apart from the lead portions 110L. The adhesive film 210 may include a die attach film. The adhesive film 210 may include an insulating polymer.

The bonding wires 300 may be provided on the top surface of the semiconductor chip 200 and the lead frame 100. The bonding wires 300 may be connected to the chip pads 250 and the conductive patterns 150. Accordingly, the semiconductor chip 200 may be electrically connected to the lead frame 100 through the bonding wires 300. The bonding wires 300 may include metal such as gold (Au), copper (Cu), silver (Ag), and/or alloys thereof. According to embodiments, since the conductive patterns 150 have a thickness of 3 μm to 7 μm, the bonding force between the conductive patterns 150 and the bonding wires 300 may be improved.

The molding film 400 may be provided on the lead frame 100 to cover the top surface and sidewalls of the semiconductor chip 200. The molding film 400 may be provided on the first surface 111 of the base frame 110 and the conductive patterns 150 to cover the siloxane layer 170. The molding film 400 may seal the bonding wires 300. The molding film 400 may include a material different from the siloxane layer 170 and the adhesive film 210. For example, the molding film 400 may include an insulating polymer such as an epoxy-based molding compound (EMC).

The molding film 400 may have relatively low adhesion to the base frame 110 and the conductive patterns 150. Accordingly, when the operation of the semiconductor package 1 is repeated, the molding film 400 may be peeled off from the base frame 110 or the conductive patterns 150.

According to embodiments, the siloxane layer 170 may be disposed between the base frame 110 and the molding film 400 and between the conductive patterns 150 and the molding film 400. Accordingly, the molding film 400 may be in contact with the siloxane layer 170 but may be spaced apart from the base frame 110 and the conductive patterns 150. According to embodiments, since R₁ in Formula 1 includes the functional groups described above, the bonding force between the molding film 400 and the siloxane layer 170 may be strong. For example, the bonding force between the molding film 400 and the siloxane layer 170 may be greater than the bonding force between the molding film 400 and the base frame 110, and may be greater than the bonding force between the molding film 400 and the conductive patterns 150. Accordingly, even when the semiconductor package 1 operates for a long period of time, the molding film 400 may be well bonded to the lead frame 100 by the siloxane layer 170. The reliability of the semiconductor package 1 may be improved. The bonding force between the molding film 400 and the siloxane layer 170 may include, but is not limited to, an adhesion force.

According to embodiments, the molding film 400 may extend further into the inner wall of the hole 118. The siloxane layer 170 is disposed between the inner wall of the hole 118 and the molding film 400, so that the molding film 400 may be firmly bonded to the inner wall of the hole 118 by the siloxane layer 170.

The siloxane layer 170 further covers the second surface 112 of the base frame 110 to prevent the base frame 110 from being damaged by external impurities (for example, oxygen or moisture). Accordingly, the corrosion resistance of the lead frame 100 may be improved.

Unlike illustrated, the molding film 400 may extend further onto the second surface 112 of the base frame 110. In this case, the siloxane layer 170 is disposed between the second surface 112 of the base frame 110 and the molding film 400, so that the molding film 400 may be well bonded to the second surface 112 of the base frame 110 by the siloxane layer 170.

When the rough process described in connection with FIG. 1 is further performed on the first surface 111 of the base frame 110, the molding film 400 may be firmly bonded to the first surface 111 of the base frame 110 by the siloxane layer 170.

According to embodiments, the lead frame 100 and the semiconductor package 1 including the same may have improved durability and reliability.

According to embodiments of the present disclosure, a lead frame includes a siloxane layer, and the siloxane layer may have a strong bonding force to a molding film. Accordingly, the molding film may be firmly bonded to the lead frame through the siloxane layer. The durability and reliability of semiconductor packages may be improved.

According to embodiments, reacting the silicon-containing compound with the hydroxyl group of the oxide layer may be performed in a single process with forming the oxide layer. Accordingly, the manufacturing process of the lead frame may be simplified, and process efficiency and productivity may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method of manufacturing a lead frame, the method comprising:
preparing a base frame on which a conductive pattern is formed;
preparing a surface treatment solution containing an alkaline substance and a silicon-containing compound; and
forming a siloxane layer on the conductive pattern by applying the surface treatment solution onto the base frame, wherein
the forming of the siloxane layer includes:
forming an oxide layer including a hydroxyl group bonded to the conductive pattern; and
bonding the silicon-containing compound to the conductive pattern by causing the hydroxyl group and the silicon-containing compound to react with each other, and
the reacting of the silicon-containing compound and the forming of the oxide layer are performed in a single process.

2. The method of claim 1, wherein
the forming of the siloxane layer is performed by an electro-deposition process.

3. The method of claim 2, wherein
the electro-deposition process is performed for 0.1 seconds to 600 seconds under a current density condition of 0.1 A/dm² to 50 A/dm².

4. The method of claim 1, wherein
the forming of the siloxane layer is performed by a dipping process.

5. The method of claim 1, wherein
the silicon-containing compound includes a material represented by Formula 1:
R₁—(CH₂)ₙ—Si—(OR₂)₃ Formula 1
wherein, in Formula 1, R₁ comprises one selected from —NH₂, —SH, a glycidyloxy group, a substituted or unsubstituted amino group having 1 to 10 carbon atoms, a substituted or unsubstituted alkyl sulfide group having 1 to 10 carbon atoms, a substituted or unsubstituted mercapto group having 1 to 10 carbon atoms, a substituted or unsubstituted epoxide group having 1 to 10 carbon atoms, and a substituted or unsubstituted ether group having 1 to 10 carbon atoms, and R₂ is an alkyl group having 1 to 5 carbon atoms, and n is an integer from 1 to 50.

6. The method of claim 5, wherein
R₂ in Formula 1 is an ethyl group or a methyl group.

7. The method of claim 5, wherein
the alkaline substance includes at least one of NaOH, Na₂CO₃, and/or Na₂SiO.

8. The method of claim 5, wherein
a concentration of the silicon-containing compound in the surface treatment solution is 0.0001 g/L to 10 g/L.

9. The method of claim 8, wherein
the alkaline substance includes a first alkaline substance, a second alkaline substance, and a third alkaline substance, which are different from each other,
a concentration of the first alkaline substance is 10 g/L to 200 g/L,
a concentration of the second alkaline substance is 10 g/L to 200 g/L, and
a concentration of the third alkaline substance is 10 g/L to 200 g/L.

10. The method of claim 1, wherein
the silicon-containing compound includes at least one of (3-aminopropyl)triethoxysilane, 3-mercaptopropyltrimethoxysilane, and (3-glycidyloxypropyl)triethoxysilane.

11. The method of claim 1, wherein
the conductive pattern exposes at least a portion of a first surface of the base frame, and
the siloxane layer is further formed on the exposed first surface of the base frame.

12. The method of claim 11, wherein
the base frame includes a first metal,
the conductive pattern includes a second metal different from the first metal,
the siloxane layer on the base frame is bonded to the first metal, and
the siloxane layer on the conductive pattern is bonded to the second metal.

13. The method of claim 12, wherein
the siloxane layer on the conductive pattern is connected to the siloxane layer on the base frame.

14. The method of claim 1, wherein
the preparing of the base frame includes:
forming a hole passing through a first surface and a second surface of the base frame to form a die pad portion and a lead portion which are spaced apart from each other; and
forming the conductive pattern on a first surface of the base frame.

15. The method of claim 14, further comprising performing a rough process on the first surface of the base frame.
